(19) United States
(12) Patent Application Publication
(10) Pub. No.: US 2017/0288080 A1
(43) Pub. Date: Oct. 5, 2017

(54) Luminescent Electricity-Generating Window for Plant Growth

(71) Applicant: The Regents of the University of California, Oakland, CA (US)

(72) Inventors: Sue A. Carter, Scotts Valley, CA (US); Glenn B. Alers, Scotts Valley, CA (US); Michael E. Loik, Felton, CA (US)

(21) Appl. No.: 15/627,100

(22) Filed: Jun. 19, 2017

Related U.S. Application Data
(63) Continuation of application No. 14/372,389, filed on Jul. 15, 2014, now abandoned.
(60) Provisional application No. 61/594,477, filed on Feb. 3, 2012.

(51) Int. Cl. H01L 31/055; A01G 7/04; A01G 9/24

(52) U.S. Cl. CPC H01L 31/055; Y02E 10/52; Y02P 60/146; A01G 9/243; Y02P 60/124; A01G 7/045

(57) ABSTRACT

A window for a greenhouse is provided that is comprised of a sheet of luminescent material [104] and light-energy converter [103]. The sheet comprises one or more luminescent materials [104] that absorb the peak wavelengths of the sun, emitting the absorbed photons to wavelengths primarily between 600 and 690 nm where they are converted to electrical power and/or enhance plant production. The luminescent material [104] is also transparent to a fraction of the wavelengths in the blue and red-portion of the solar spectrum which are required for plant growth and flowering. An additional polymer layer may be added as a luminescent layer, diffuser and/or IR reflector to further enhance plant growth and electricity generation.

### CROSS-REFERENCE TO RELATED APPLICATIONS

This application is a continuation of Ser. No. 14/372,389 filed on Jul. 15, 2014, which is a 371 of PCT application PCT/US2013/024393 filed on Feb. 1, 2013. PCT/US2013/024393 filed on Feb. 1, 2013 claims the benefit of U.S. Provisional application 61/594,477 filed on Feb. 3, 2012.

### FIELD OF THE INVENTION

This invention relates generally to luminescent solar collectors and building integrated photovoltaic windows.

### BACKGROUND OF THE INVENTION

Luminescent Solar Collectors (LSCs) are beneficial for capturing solar energy for conversion to electrical power. An LSC has a sheet containing a fluorescent material that absorbs solar radiation from the sun after which it emits photons to longer wavelengths through the process of photoluminescence or fluorescence. The light, or photons, that are emitted through this process are waveguided (via total internal reflection) down a sheet that is coupled to a photovoltaic cell or solar cell that converts the light to electrical power. Current approaches of LSCs focus on maximizing the power conversion efficiency of the LSC with little regard to the application of this technology as building integrated PV windows for greenhouses and related structures where plant growth is important.

Adjusting the spectrum, or color, of light is known to be benefitial to certain plant functions like vegetative growth, flowering and fruiting.

Accordingly, there is a need in the art for luminescent solar collectors which are can produce power with no harm to plant growth.

### SUMMARY OF THE INVENTION

Disclosed, in various embodiments, are luminescent solar collectors which have an absorption and optical designed for both plant growth and power production for applications involving plant growth under windows having LSCs, including greenhouses, atriums, solariums, skylights and agricultural covers. For example, the relative absorption of the luminescent sheet in the blue/green/red portions of the spectrum is determined specifically to not degrade plant growth.

In an exemplary embodiment, the luminescent solar collector has a luminescent sheet and light energy converter. The sheet can include or is a polymer material containing a fluorescent material dispersed therein. The fluorescent material absorbs greater than 40% of the solar photons between 500 and 600 nm, absorbs less than 70% of the solar photons between 410 and 490 nm, and absorbs less than 40% of the solar photons between 620 and 680 nm. This ratio of absorption in each band is chosen for optimum photosynthesis and plant growth. The polymer layer is designed to transmit the radiated light to the light energy converter and wherein the light energy converter is optically coupled o the luminescent sheet. The luminescent sheet may be further attached to an additional glass, acrylic, or polycarbonate-based substrate in such a manner that the luminescent light is optically coupled to the substrate. The absorption of the luminescent sheet is controlled by the choice of luminescent dye and the concentration. Luminescent sheets that absorb too much light in the bands specified above will harm the plant growth. Sheets that absorb too little light in the above bands will benefit little from power generation.

In other embodiments, the fluorescent material dilution in the polymer material, measured in weight percent of fluorescent material by weight polymer, multiplied by the thickness of the luminescent sheet, measured in millimeters, is between 0.005 to 0.05 to achieve an optical density (absorption) in the range specified above.

In further embodiments, the fluorescent material is selected as a fluorescent dye, conjugated polymer, or a quantum dot wherein the fluorescent dye is based on perylene, terrylene or rhodamine, the conjugated polymer is a polyfluorene, polythiophene, or polyphenylenevinylene, and the quantum dot is comprised of CdTe, CdS, CdSe, PbS, PbSe, GaAs, InN, InP, Si or Ge and the light energy converter is a photovoltaic comprised of silicon, gallium arsenide, copper indium gallium selenide, or cadmium telluride as the active absorbing layer.

In other embodiments, the front active face of the light-energy converter (PV cell) is attached parallel to the surface of the luminescent sheet and the back face is encapsulated with an additional polymer layer or attached to the structural frame of the greenhouse. The active area of the light converter is between 5% to 25% of the active area of the luminescent sheet.

In other embodiments, an additional sheet or sheets of an IR-emitting material, a diffuser, and/or and IR-absorber/reflector are added to further improve efficiency and plant growth while reducing cooling costs. In some embodiments, the luminescent solar collector absorbs greater than 30% of the light in the far-red region between 700 nm and 900 nm.

The luminescent energy-conversion greenhouse of the present disclosure is described herein with reference to exemplary embodiments. Modifications and alternations will occur to others upon reading and understanding the description. It is intended that the exemplary embodiments be constructed as including all such modifications and alternation insofar as they come within the scope of the invention or the equivalents thereof. Exemplary embodiments of the invention can be summarized, without any limitation, according to the following statements.

In one example, the invention pertains to a luminescent solar collector having a absorption optimized for plant growth and electrical power generation with a luminescent sheet and a light energy converter. The luminescent sheet comprises a polymer material containing single or multiple fluorescent material(s) dispersed therein, wherein the fluorescent material(s) absorbs and emits light that is ideal for plant growth with greater than 50% of the solar photons between 500 and 600 nm, absorbs less than 70% of the solar photons between 410 and 490 nm, and absorbs less than 50% of the solar photons between 620 and 680 nm, and wherein the polymer layer is designed to transmit the radiated light to the light energy converter. A light energy converter can be optically coupled to the luminescent sheet.

In another example, one could have a luminescent solar collector, wherein the luminescent sheet is also optically connected to a substrate that is largely transparent between 400 and 700 nm.

In yet another example, one could have a luminescent solar collector, wherein the polymer material is comprised of a material containing poly (alkyl methacrylates), polycarbonate, or a derivative, or combination thereof.

In yet another example, one could have a luminescent solar collector, wherein the fluorescent material emits at least 50% of the radiated photons with wavelengths between 600 and 690 nm.

In yet another example, one could have a luminescent solar collector, wherein the percentage of solar photons absorbed between 410 nm and 490 nm or between 620 nm and 680 nm is less than the percentage of solar photons absorbed between 500 and 600 nm to optimize plant growth.

In yet another example, one could have a luminescent solar collector, wherein the concentration of the fluorescent dye in the polymer material, measured in weight percent, multiplied by the thickness of the sheet, measured in millimeters, is between 0.005 to 0.05.

In yet another example, one could have a luminescent solar collector, wherein the photoactive surface of the light energy converter in mounted approximately parallel to the plane of the luminescent sheet.

In yet another example, one could have a luminescent solar collector, wherein the back surface of the light energy converter in mounted on a supportive frame.

In yet another example, one could have a luminescent solar collector, where the percentage of active area of the light energy converter to the active area of the luminescent sheet is between 5% and 35%.

In yet another example, one could have a luminescent solar collector, wherein the light energy converter is silicon, gallium arsenide, copper indium gallium selenide or cadmium telluride photovoltaic.

In yet another example, one could have a luminescent solar collector, wherein an additional transparent sheet is added behind the light-energy converter for purposes of protection.

In yet another example, one could have a luminescent solar collector, wherein a second luminescent sheet is added that contains a fluorescent material which absorb less than 50% of the solar photons between 620 and 680 nm, and wherein the luminescent sheet is optically coupled to the light energy converter.

In yet another example, one could have a luminescent solar collector, wherein the luminescent sheet is textured so that transmitted light is diffuse.

In still another example, one could have a luminescent solar collector, wherein additional single or multiple non-luminescent sheets are added that contain a light diffuser, an IR-absorber, a IR-reflector, or combination thereof.

### BRIEF DESCRIPTION OF THE DRAWINGS

The present invention together with its objectives and advantages will be understood by reading the following description in conjunction with the drawings, in which:

FIG. 1 shows a simplified dragram according to an exemplary embodiment of the invention representative examples (a) and (b) of the LSC architecture. Glass or plastic transparent substrate 101. One or more adhesives 102. The light-energy converter 103, such as a photovoltaic cell. The luminescent sheet 104.

FIG. 2 shows a simplified diagram according to an exemplary embodiment of the invention a representative example of an LSC architecture where the PV cell is attached to a rigid frame that is non-transparent. One or more adhesives 202. The light-energy converter 203, such as a photovoltaic cell. The luminescent sheet 204. A rigid frame 205.

FIG. 3 shows a simplified diagram according to an exemplary embodiment of the invention absorption and photoluminescence for a typical fluorescent dye (BASF Lumogen 305) optimized for power generation and plant growth. The two curves are for absorptance 300 and P.L. 301.

FIG. 4 shows a simplified diagram according to an exemplary embodiment of the invention photosynthesis data on tomato plants showing the negative impact on the efficiency of the Photosystem II (top) and electron transport rate (bottom) for luminescent dye concentrations where absorption over visible spectrum has not been optimized for plant growth. These concentrations have an optical absorption that is too high in the red and blue for efficient plant growth.

FIG. 5 is a graph of percent absorption vs. wavelength, which shows according to an exemplary embodiment of the invention the range of absorptions that are optimized for both power efficiency and plant growth for Lumogen Red 305. The middle concentration 250F represents the desired absorption.

FIG. 6 is a simplified diagram of current vs. voltage, which shows according to an exemplary embodiment of the invention typical IV-curve for a full assembled LSC window optimized for plant growth, with a power efficiency of approximately 4%. The two curves are for bare cell 600 and for LSC with cells spaced by 13 cm 602.

### DETAILED DESCRIPTION

### Device Structure

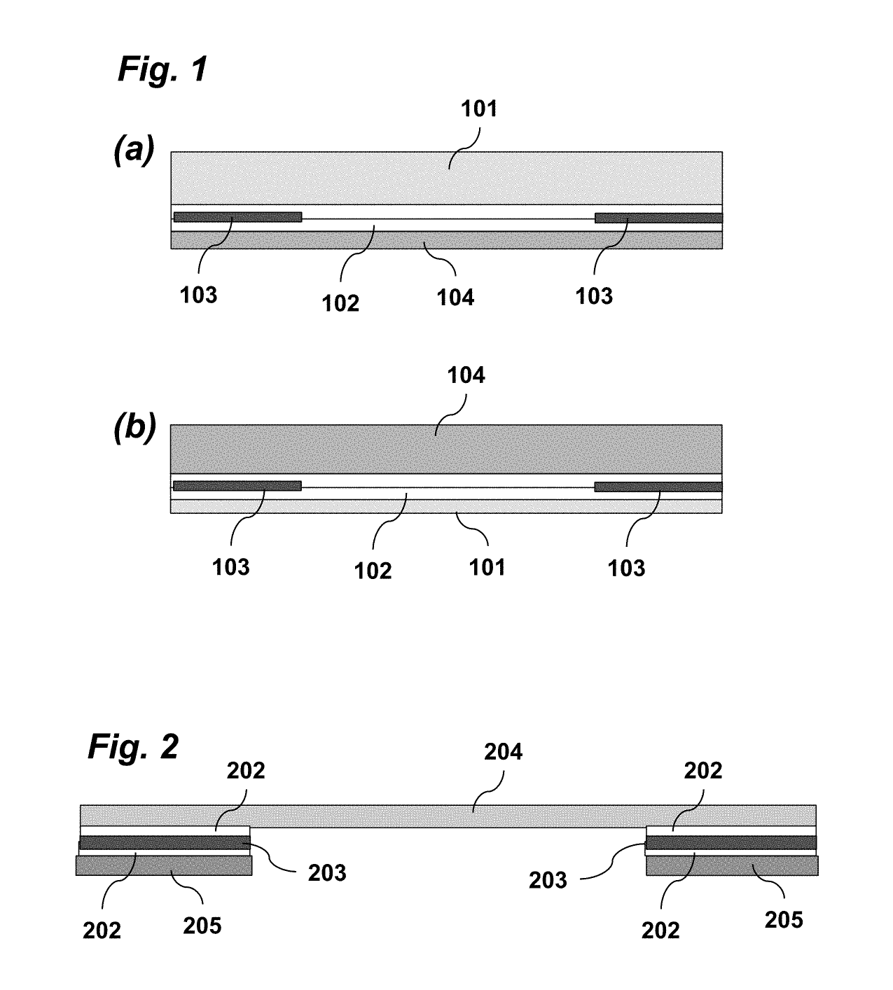

The LSC device diagram described here is shown in FIGS. 1 and 2. A luminescent sheet is fabricated by casting, injection molding, blown films, and related methods so that the luminescent dye is directly imbedded into plastic sheet, that is typically comprised of a material related to acrylic or polycarbonate. The luminescent material may also be deposited from a solvent solution containing the dye, plastic, and suitable solvent through a print-based process, such as gravure, flexography, screen-printing, slot-coating or bar-coating. The luminescent material is typically printed or laminated onto clear substrate that is largely transparent to the PAR (photoactive response) spectrum of plants between 380 to 780 nm. Representative substrates include all window materials used for greenhouses, including (but not limited to) glass, polycarbonate, polyethylene, and acrylic. Substrates that have higher transmission between 600 and 700 nm are preferred, such as low-iron glass and acrylic. The resulting thickness of the luminescent sheet and substrate is typically between 1 mm and 6 mm, but can be thinner than 100 microns for flexible luminescent sheets. The light converter cell is optically coupled to the luminescent sheet using a clear adhesive or laminate. Multiple other sheets, as described in detail below, and may be added to improve power efficiency, plant growth or for protection purposes. Connectors are added to the light energy converter so that the electricity generated can be externally harnessed.

### The Luminescent Sheet and Impact on Power Efficiency and Plant Activity

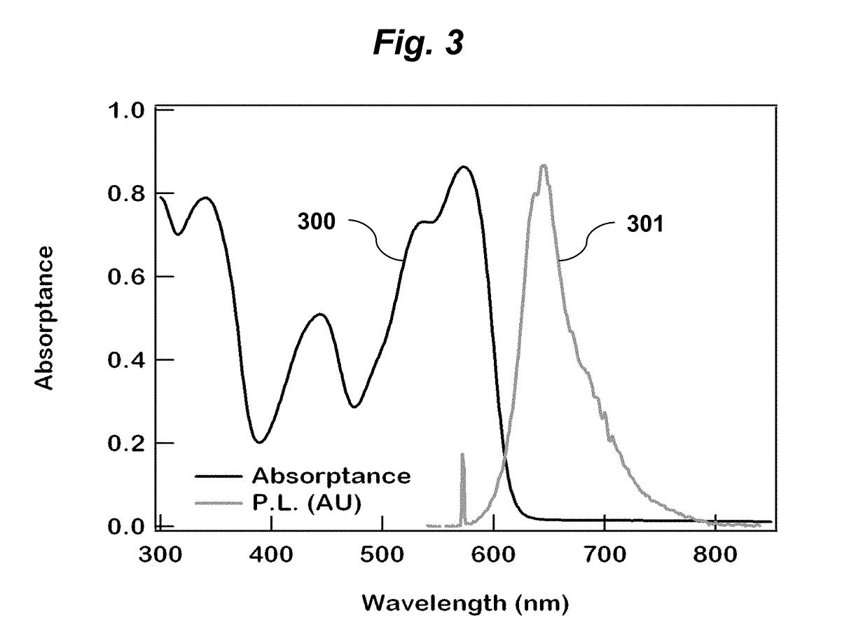

The ideal fluorescent material for the luminescent sheet has of a fluorescent dye with a quantum yield greater than 50% and emits a majority of its photons between 600 and 690 nm, where chloropyll a and b are most active. The fluorescent dye is also chosen to minimize overlap between the absorption spectra and fluorescence spectra as well as to minimize the absorption of light that is absorbed by chloropyll a and b (between 410 and 490 nm and between 620 and 680 nm) while maximizing the light absorption in the remaining portions of the solar spectrum (i.e. 380 to 410 nm, 490 to 620 nm, and 680 nm to 780 nm). Red-emitting materials from perylene and rhodamine family meet many of these criteria. In particular, the series of red-emitting Lumogen dyes, including LR305, contains the more promising candidates for this application; however, there are other materials, including those yet to be discovered, that could result in better overall performance. As shown in FIG. 3, LR305 has overlap between its absorption and emission around 600 nm, as well as substantial absorption between 410 and 490 nm, which could be improved upon for greater power generation and to help plant growth in species that require less blue absorption.

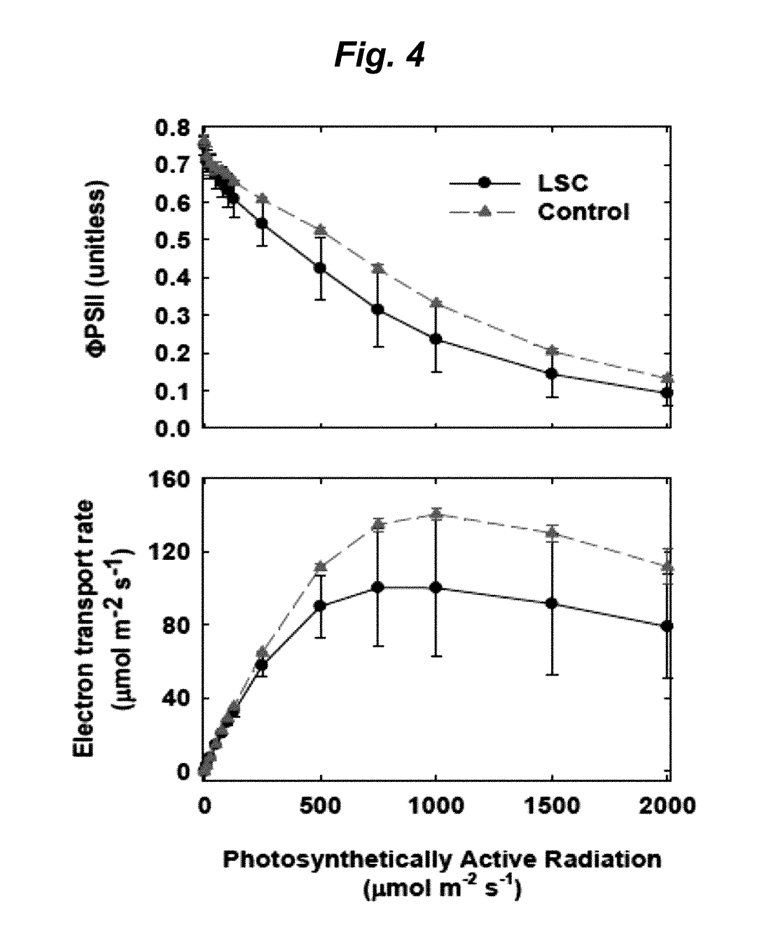

The dye can be diluted into the polymer host to maximize the photoluminescence efficiency or quantum yield. The polymer host is chosen to be largely transparent to the PAR spectrum (i.e. 380 to 780 nm) and to be chemically compatible with the fluorescent material. For solution deposited films, the polymer and fluorescent material should have a compatible solvent. Many fluorescent dyes undergo photoluminescence quenching at concentrations above 0.5% in the polymer host. We observe an optimal range for the luminescent dye Lumogen 305 between 0.2% and 0.001%, which depends both on the absorption coefficient of the dye and the thickness of the luminescent sheet. Typically, the luminescent dye is added to the polymer material to maximize the surface photoluminescence. To harvest as much of the solar photons as possible, this concentration results in a peak absorption above 90%. However, such high absorption can result in reduction in the photosynthetic activity in plants. The impact on plant photosynthesis is shown in FIG. 4 and is attributed to too high absorption of the blue (410 to 490 nm) photons that are absorbed by chlorophyll and normally attributed to plant growth. Luminescent sheets with blue absorption less than 50% have been shown to have less impact, and in some cases, positive plant growth (Novaplansky).

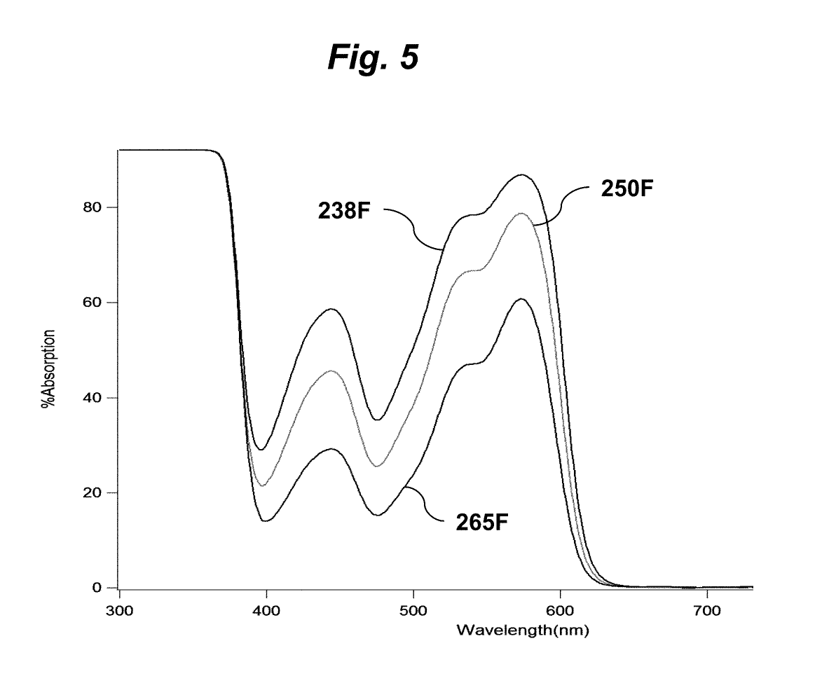

The typical upper, lower and near optimal absorptions for the luminescent Lumogen 305 dye to optimize both power production and plant growth is shown in FIG. 5 and further described in Table 1. These results are for dye diffused into a 3 mm thick acrylic substrate with concentration ranging from 0.0086% (238F) to 0.0032% (265F) LR305 in PMMA. Similar results have been obtained in luminescent sheets that are 500 micron thick and below 100 microns thick, with the concentration scaling according to Beer's law. The maximum power generation of the LSC does not occur at maximum absorption (i.e. 238F) due to greater self-absorption at higher concentrations; however, at sufficiently low absorption (i.e. 265F), a reduction in current and therefore power loss does occur due to too little absorption.

Overall, we determine that the concentration of the fluorescent dye in the polymer material, measured in weight percent, multiplied by the thickness of the sheet, measured in millimeters, should be between 0.005 to 0.05 for most fluorescent materials, although a fluorescent material that is engineered with anomalous high or low absorption coefficient may fall outside this range. Furthermore, the percentage of absorption of blue photons (410 to 490 nm) should be less than 70%, the percentage of absorption of green photons (500 nm to 600 nm) should be greater than 50%, the percentage of absorption of red photons (620 nm to 680 nm) should be less than 50%, and that overall, the percentage of absorption of the blue or red photons should be less than the absorption of green photons, as defined above. Optimal films may typically have blue absorption less than 50%, green absorption above 70% and red absorption below 10%. Here, we define the percentage of photons absorbed as the number of photons absorbed by the luminescent sheet over the spectral range indicated divided by the total number of solar photons incident on the luminescent sheet over the spectral range indicated, converted to percentage. Finally UV stabilizers and oxygen/H2O scavengers can be added to the luminescent sheet to improve photoluminescence stability.

While the results presented here focus on fluorescent materials that are small molecule organics, this should not be construed as limiting. We have also shown (Sholin) that quantum dot and semiconducting polymers can be used as luminescent materials for this application. In particular, polyspiro red has a similar absorption/emission to LR305 and a larger Stokes-shift, making it a possible suitable replacement material. We also note that the fluorescent material may include a combination of one or more fluorescent materials that have different absorption but have a majority of their emission over a similar wavelength, namely between 600 to 690 nm.

### The Light-Energy Converter

The light-energy converter absorbs the luminescent light that is waveguided down the luminescent sheet using total internal reflection and converts it to electrical power. The light-energy converter is typically a photovoltaic (PV). The PV should have high quantum efficiency (>60%) between 600 and 690 nm where a majority of the fluorescent light is emitted. Many Silicon (Si)-based, Gallium Arsenide (GaAs), Cadmium Telluride (CdTe), and Copper Indium Gallium Selenide (CIGS) photovoltaics meet this criteria, as well as photovoltaic technologies which are yet to emerge as commercial products. The photovoltaic is cut into strips that can be mounted either on the edge, or perpendicular, to the luminescent sheet (the standard LSC configuration) or on the front or parallel to the luminescent sheet. For the edge mounted cells, the strips are cut at or about the thickness of the luminescent sheet. For the face mounted cells, the strips are between 2× and 20× wider than the thickness of the luminescent sheet, with thinner strips resulting in greater contributions of the luminescent sheet to the overall power efficiency. The face-mounted configuration, as depicted in FIG. 1 and FIG. 2, is the preferred orientation because of lower cost of manufacturing and because power can be harvested directly from the PV itself, resulting in higher power efficiency. The PV cells are mounted across the face of the luminescent material to optimize power gain from the LSC as well as overall power efficiency. For greenhouse applications, the area of the PV cell should be between 5% to 35% of the total area of the luminescent sheet. Higher percentage (˜35%) leads to higher power efficiencies, but also more shading of plants, degraded growth and higher cost. Lower percentage (˜5%) leads in lower power efficiencies and costs, and less shading. A coverage between 10% and 20% provides a good balance between cost, plant growth, and power efficiency.

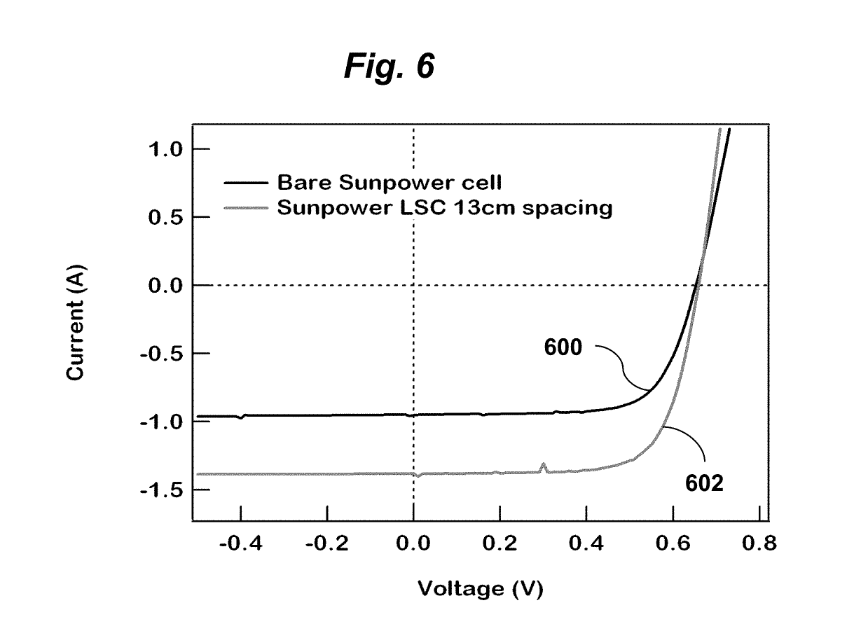

The individual strips of photovoltaic cells are wired in series or parallel with the wires coming out of the LSC package so they can be easily connected to. A typical IV curve for a greenhouse window with and without the luminescent material is shown in FIG. 6. The luminescent material LR305 can increase the power output of the PV cell between 1.25× to 3× depending on the PV cell and LR305 concentration, with percentage coverages between 35% and 5%, respectively.

### Additional Polymer Films

An additional IR-emitting luminescent material may be added above or below the luminescent sheet in order to improve power efficiency and reduce heating of the greenhouse. This IR-luminescent material should have a photoluminescence quantum yield above 20%, should emit at wavelengths between 700 and 950 nm for single or polycrystalline Si light-energy converters (700 to 850 nm for other forms of Si, CdTe, CIGS, and GaAs light-energy converters) and should absorb less than 50% of the photons between 620 nm and 680 nm to assure that these wavelengths are transmitted to the plants. The IR-emitting luminescent material must be optically coupled to the light-energy-converter and will normally be mounted below the first luminescent film so that the solar light is incident on the first luminescent film before being incident on the IR-emitting luminescent film.

A non-luminescent IR-absorbing or reflecting film may also be added in order to decrease heating of the greenhouse. This IR-reflecting film does not need to be optically coupled to either the PV cell or luminescent sheet, but may be laminated at the back of the PV cell to provide additional protection. Generally, the IR-reflecting film would be located below the luminescent sheet; however, there may be instances where the reverse configuration is desirable.

A light diffusing layer may be added within or below the luminescent sheet to provide more even lighting within the greenhouse structure. The diffusing film might contain white scattering particles or a texture in the luminescent sheet that slightly redirects light that is transmitted through the glass thus providing a more uniform light on the plants. This diffusing film may also scatter some light back to the luminescent sheet, providing an additional chance for the transmitted light to be absorbed and converted to electrical power.

TABLE 1
Relative power outputs and absorption of photons over different ranges
for the luminescent sheets presented in FIG. 5. The optimal concentration
of power and plant growth occurs around or about the 250 F sample.

| | % of Solar | % of Solar | % of Solar | |
|---|---|---|---|---|
| Lumogen | photons | photons | Photons | |
| 305 | absorbed | absorbed | absorbed | Relative |
| Sample | 400-490 nm | 500-600 nm | 600-690 nm | Current |
| 238 F | 69 | 82 | 8 | 1.22 |
| 250 F | 53 | 71 | 6 | 1.44 |
| 265 F | 31 | 47 | 3 | 1 |

### Examples of Device(s)

The following description includes one or more device examples according to the invention, which not meant to be exclusionary of any other designs that have been described.

### Example 1

The 3 mm thick luminescent sheet contains polymethylmethacrylate (PMMA) with a fluorescent dye, Lumogen 305, is diluted into the sheet at a concentration of 0.006% by weight percent of Lumogen 305 in PMMA. A silicon PV cell is attached directly to the acrylic using an optical clear glue that is thermally stable above 85 C and allows for differential thermal expansion. A thin plastic sheet is laminated to the back of the substrate for protection. At 16% area of PV per area of luminescent sheet, the power efficiency is approximately 4%. The sheet absorbs less than 60% of the photons between 410 and 490 nm and less than 10% of the photons between 620 and 680 nm, and approximately 70% of the photons between 500 and 600 nm.

### Example 2

The 0.5 mm thick luminescent sheet contains polymethylmethacrylate (PMMA) with a fluorescent dye, Lumogen 305, diluted into the sheet at a concentration of 0.03% by weight percent of LR305 in PMMA. This film and the silicon PV cells are laminated to a glass or acrylic sheet that is 3 mm thick using EVA. A thin glass sheet is laminated with EVA to the back of the substrate for protection purposes. At 16% coverage, the power efficiency is approximately 4.5% and the sheet absorbs less than 60% of the photons between 410 and 490 nm and less than 10% of the photons between 600 and 690 nm, and approximately 70% of the photons between 500 and 600 nm.

### Example 3

The 0.2 mm thick luminescent sheet contains polymethylmethacrylate (PMMA) with a fluorescent dye, Lumogen 305, diluted into the sheet at a concentration of 0.1% by weight percent of Lumogen 305 in PMMA. The silicon PV cell is attached to a supporting frame, and the luminescent sheet is coupled to the silicon PV using an optical glue. At 10% coverage, the power efficiency is approximately 3% and the sheet absorbs less than 50% of the photons between 410 and 490 nm and less than 10% of the photons between 600 and 690 nm, and approximately 60% of the photons between 500 and 600 nm.

1. A luminescent solar collector designed for both plant growth and electrical power generation, the luminescent solar collector comprising a luminescent sheet and a light energy converter optically coupled to the luminescent sheet; wherein the luminescent sheet comprises a polymer material containing single or multiple fluorescent material(s) dispersed therein, wherein the fluorescent material(s) absorbs greater than 50% of solar photons between 500 and 600 nm, absorbs less than 70% of solar photons between 410 and 490 nm, and absorbs less than 50% of solar photons between 620 and 680 nm, and wherein the polymer material transmits radiated light to the light energy converter.

2. The luminescent solar collector of claim 1, wherein the luminescent sheet is also optically connected to a substrate that is transparent between 400 and 700 nm.

3. The luminescent solar collector of claim 1, wherein the polymer material is comprised of a material containing poly (alkyl methacrylates), polycarbonate, fluorinated polymer or a derivative or combination thereof.

4. The luminescent solar collector of claim 1, wherein the fluorescent material(s) emit at least 50% of radiated photons with wavelengths between 600 and 690 nm.

5. The luminescent solar collector of claim 1, wherein a percentage of solar photons absorbed by the fluorescent material(s) between 410 nm and 490 nm is less than a percentage of solar photons absorbed by the fluorescent material(s) between 500 and 600 nm, and wherein a percentage of solar photons absorbed by the fluorescent material(s) between 620 nm and 680 nm is less than a percentage of solar photons absorbed by the fluorescent material(s) between 500 and 600 nm.

6. The luminescent solar collector of claim 1, wherein a concentration of the fluorescent material(s) in the polymer material, measured in weight percent, multiplied by the thickness of the luminescent sheet, measured in millimeters, is between 0.005 and 0.05.

7. The luminescent solar collector of claim 1, wherein a photoactive surface of the light energy converter is mounted approximately parallel to a plane of the luminescent sheet.

8. The luminescent solar collector of claim 1, wherein a back surface of the light energy converter is mounted on a supportive frame.

9. The luminescent solar collector of claim 1, where a percentage of active area of the light energy converter to an active area of the luminescent sheet is between 5% and 35%.

10. The luminescent solar collector of claim 1, wherein the light energy converter is composed of silicon, gallium arsenide, copper indium gallium selenide or cadmium telluride photovoltaic.

11. The luminescent solar collector of claim 1, further comprising an additional transparent sheet positioned behind the light-energy converter for purposes of protection.

12. The luminescent solar collector of claim 1, further comprising a second luminescent sheet which contains a second fluorescent material which absorbs less than 50% of solar photons between 620 and 680 nm, and wherein the second luminescent sheet is optically coupled to the light energy converter.

13. The luminescent solar collector of claim 1, further comprising additional single or multiple non-luminescent sheets which contain a light diffuser, an IR-absorber, a IR-reflector, or a combination thereof.

14. The luminescent solar collector of claim 1 in which the backsheet material is textured to make the transmitted light diffuse.

15. The luminescent solar collector of claim 1 in which the ratio of red transmission between 620 and 680 nm to blue transmission between 410 nm and 490 nm is greater than 1.

16. A luminescent solar collector of claim 1 that absorbs greater than 30% of the light in the far-red region between 700 nm and 900 nm.
